(19) United States
(12) Patent Application Publication
(10) Pub. No.: US 2004/0070104 A1
(43) Pub. Date: Apr. 15, 2004

(54) Method for making heat-shrinkable skirt caps and resulting caps

(76) Inventor: Jacques Granger, Libourne (FR)

Correspondence Address: DENNISON, SCHULTZ, DOUGHERTY & MACDONALD, 1727 KING STREET, SUITE 105, ALEXANDRIA, VA, 22314, US

(21) Appl. No.: 10/399,775

(22) PCT Filed: Nov. 23, 2001
(86) PCT No.: PCT/FR01/03700

(30) Foreign Application Priority Data
Nov. 28, 2000 (FR) 00/15344

(51) Int. Cl. B29C 35/10; B29C 47/20; B29C 47/88; B29C 47/90; B26D 3/16; H01J 37/30; B29C 55/24

(52) U.S. Cl. 264/150; 264/470; 264/473; 264/477; 264/209.3; 264/151; 264/564; 264/566; 264/568; 264/209.6; 264/211.13; 264/230; 264/268

(57) ABSTRACT

The invention concerns a method which consists in: a) forming by extrusion an extruded thermoplastic tube (20) having, when coming out of the extruder, a diameter D₁; b) then subjecting said extruded tube of diameter D₁ to a radiation treatment, so as to produced a cross-linked tube (21); c) after bringing said cross-linked tube (21) to a temperature not less than a temperature substantially equal to the melting point of its crystalline phase, subjecting it, in displacement, to a radial monoaxial expansion for form an expanded tube (22) of diameter D₂, then cooling it down to a temperature, typically room temperature, at which it can be cut into tube portions (23) with length substantially equal to the height of said caps (1); and e) assembling or forming a head (10, 100, 101, 102, 103) on said tube portion (23), so as to obtain a cap or top (1), with heat-shrinkable skirt, economical and having a homogeneous skirt (11, 12) free of axial connection line.

### FIELD OF THE INVENTION

The invention relates to the field of closing caps for receptacles or bottles or overcaps for receptacles or bottles previously closed by a cork, a closing disk or any other closing means.

More particularly, the invention relates to the field of closing caps with a heat shrinking skirt, in other words caps formed from a thermoplastic material which, during fitting, are shrunk onto the neck by adding thermal energy, as opposed to metal overcaps in which the skirt is applied and deformed in contact with the glass ring in the bottleneck to be crimped while the cap is being fitted.

More specifically, the invention relates to a new process for making caps with a heat shrinking skirt, overcaps and possibly closing caps with a heat shrinking skirt.

### STATE OF THE ART

Heat shrinking (HS for short) caps have been known for a long time.

Thus, patent FR 805.771 describes the manufacture of a cap based on PVC formed by extrusion of a PVC based tube, and then after elongation if required, expansion of the tube at the exit from the extruder, followed by cooling and cutting into portions of cylindrical tubes to form a cap without a head.

Patent GB 1,015,713 also describes a process for making HS caps in which a tube based on a PVC or PS material is made heat shrinkable by expansion, flattened and heat sealed transversely at one end so as to close it off, and is cut into portions to form a flattened cap which, after separation, forms a welded head cap that can be placed and heat shrunk onto a bottleneck.

Patent FR 2.115.137 also describes a process for making HS caps in which a blank is cut out from a sheet of heat shrinkable plastic, and a rolled HS cap is formed by welding the side edges by an approximately axial overlap. A cap head may also be bonded onto it. This cap may be combined with a bottle cork.

Patent FR 2.219.080 also describes a HS cap formed by a PVC or PS tubular part, of which one closed end that will form the head of the cap is obtained by compression and shrinkage of a portion equal to the length of the said tubular part.

Patent U.S. Pat. No. 5,118,460 describes a process for making HS caps by moulding. Similarly, patent FR 2 708 513 describes a process for making HS caps in which a preform is formed firstly by moulding, and is subsequently expanded.

### PROBLEMS THAT ARISE

Known caps or overcaps with a heat shrinking skirt (or HS caps for short), mainly overcaps, have at least one of the following disadvantages relative to unacceptable aesthetics and/or an excessive production cost:

firstly, concerning the aesthetic aspect of caps, existing requirements prevent the use of an overcap without a head, or formed from a head that is not perfectly plane.

Similarly, concerning the skirt of the cap, HS overcaps with a rolled skirt are low quality caps due to the unaesthetic appearance of the side weld of the rolled skirt.

secondly, concerning the production cost of HS caps, the most economical caps are rolled caps formed from a strip material from which blanks are cut out. Apart from traditional metal caps, the least economical caps are moulded caps.

Therefore the problem to be solved by the invention is to obtain a process leading to a cap (this term is taken to include closing caps, overcaps and overcaps for sparkling wines) that has the following characteristics and qualities all at the same time:

aesthetic qualities, with an unrolled skirt and a flat head, so that it can be competitive with “high quality” caps available in the shops, typically metal caps,

economic, with approximately the same production cost as HS overcaps with a rolled skirt.

The invention is also designed to provide a highly flexible process offering a wide variety of caps, taking account of the increasing customisation of customer needs.

### DESCRIPTION OF THE INVENTION

In the manufacturing process for caps or overcaps with heat shrinking skirts according to the invention:

a) an extruded tube is formed by extrusion of a thermoplastic material, typically chosen from among polyolefins, with a diameter D1 at the exit from the extruder,

b) the said extruded tube with diameter D1 is then subjected to an irradiation treatment so as to cross link the said polyolefin,

c) the said cross-linked tube is warmed up to a temperature equal to at least approximately the melting temperature of its crystalline phase, and is then subjected to a monoaxial radial expansion, while moving, to form an expanded tube with diameter D2, and is then cooled to the temperature at which it can be cut into portions, typically ambient temperature,

d) the said expanded tube is then cut into tube portions with the length approximately equal to the height of the said caps, and

e) a head is then assembled or formed on the said portion of tube,

so as to obtain an economical cap or overcap with a heat shrinking skirt that has a homogenous skirt with no axial connection line.

This process, which is different from the state of the art in several respects, solves all problems that arise.

Firstly, it enables the use of the most economical raw materials, namely polyolefins.

Furthermore, this process is particularly economical to the extent that, apart from the low material cost mentioned above, it uses and brings together two technologies that are inexpensive because their production is relatively efficient, namely tube extrusion and assembly of a head on a portion of the tube.

It can also be used to make overcaps or caps with a skirt that is perfectly uniform with no axial connection line, and therefore that look attractive.

The process according to the invention also opens up the possibility of a very large family of caps, particularly through the choice of materials that can be used to make the skirt and the head, the skirt being made of a coloured or uncoloured plastic, possibly transparent, or provided with particular optical effects such as nacreous reflections, the head possibly being made of metal or a multiple layer complex, or also made of plastic material like the skirt, the appearance of the head possibly being different from the appearance of the skirt.

Extrusion also includes coextrusion of different concentric layers using different thermoplastic materials or the same material but with different fillers (white filler, coloured filler or for special effects) depending on the layer, so as to be able to make a wide variety of caps with different appearances, using the same process.

### DESCRIPTION OF THE FIGURES

FIGS. 1 to 4 all relate to the invention, while FIG. 5 shows the state of the art.

All figures are diagrammatic descriptions of the different steps of the processes described.

FIG. 1 describes the process for making the skirt for the cap according to the invention, this process being common to all embodiments of the invention and particularly those shown in FIGS. 2 and 3. It also describes a first method of making and assembling the head of the cap.

FIG. 2 describes a second method of making the head of the cap, by injection.

FIG. 3 describes a third method of making the head of the cap, by moulding.

FIGS. 4a to 4f describe a fourth manufacturing method by attachment of a skirt (12) on an insert (8) with a threaded skirt, the skirt (12) being formed from the portion of tube (23).

FIGS. 4a to 4c represent the temporary assembly of the insert (8) on the end of the mandrel (401) with an end (402) adapted for this temporary assembly, the mandrel (401) and the insert (8) being shown separately in FIGS. 4a and 4b, and assembled in FIG. 4c.

FIGS. 4d to 4f illusate the formation of the cap (1), FIG. 4d illustrating the positioning of the portion of the tube (23) on the assembly composed of the mandrel (401) and the insert (8), assembly on which the portion of tube (23) retracts as illustrated in FIG. 4e, before final separation of the mandrel (401) to lead to the final cap (1) as illustrated in FIG. 4f.

FIG. 5 describes the process according to the state of the art that includes the formation of a heat shrinking rolled skirt and a head assembly similar to the first embodiment of the head shown in FIG. 1.

### DETAILED DESCRIPTION OF THE INVENTION

According to the invention, and as a possible variant, the said tube (20) at the exit from the extruder and before the said irradiation processing, may be cooled and calibrated so as to impose predetermined geometric characteristics on the said extruded tube (20).

As another variant, in step c) in the process, the said monoaxial expansion may take place completely or partly during the phase in which the tube is cooled, so that the length of the production line can be reduced.

According to the invention, the said plastic material (2) may comprise a polyolefin chosen from among PE, PP and PB, ethylene and propylene copolymers, or an elastomer, or a mix of these different polymers in the form of a single layer material or a multiple layer material. It may be useful to coextrude a tube made of a plastic material with several concentric layers. But the said plastic material may be composed of a single layer material made of a polyolefin chosen from among PE or PP. Preferably, the said polyolefin is PE.

The said plastic material (2), or at least one layer in the case of a multiple layer plastic material, may contain a micronized charge typically composed from among talc, calcium carbonate, barium sulphate, titanium oxide, organic or mineral pigments, or any other filler known to result in particular visual effects or a particular feel.

The said irradiation treatment may be an ionising radiation chosen from among β and γ radiation, but preferably the said irradiation treatment is an electronic bombardment or β radiation, typically applied to the said tube using an annular irradiation device (32) surrounding the said expanded tube.

Considering the final dimensions of the caps, themselves depending on the size of the necks of the bottles to be capped, the diameter D₁ of the extruded tube (20) may be between 10 mm and 30 mm, the ratio D₂/D₁ being between 1.5 and 4.

According to the invention, the said radial monoaxial expansion may be obtained either by keeping the inside of the said cross-linked tube (21) under pressure, or by keeping the outside of the said cross-linked tube (21) under vacuum.

Preferably, the said radial monoaxial expansion is obtained by an expansion device (34) keeping the outside of the said tube to be expanded under a vacuum.

This radial monoaxial expansion is different from the biaxial expansion in the radial and longitudinal directions. Due to this exclusively monoaxial expansion, the cap formed is retracted during its application and during capping, so as to be perfectly homogenous around the neck and to have a good tension in the skirt, such that the appearance of the heat shrunk cap after the cap has been fitted is attractive, and is an important aspect of the invention.

The said cross-linked tube may be expanded and calibrated, typically using at least one calibration ring (340), to ensure that the variation of the diameter D₂ in an expanded tube (22) with a cylindrical diameter D₂, remains less than 5%.

It was found very advantageous to obtain caps (1) with excellent geometric uniformity, particularly in terms of the diameter, so that the skirt (11) of the cap is perfectly smooth and uniform once the cap has been heat shrunk onto the neck to be capped.

This can be achieved using two calibration rings (340) that define an internal volume within the space between them, or an annular cavity (341) under a relative vacuum so as to apply a negative pressure onto the outside surface of the said tube to be expanded.

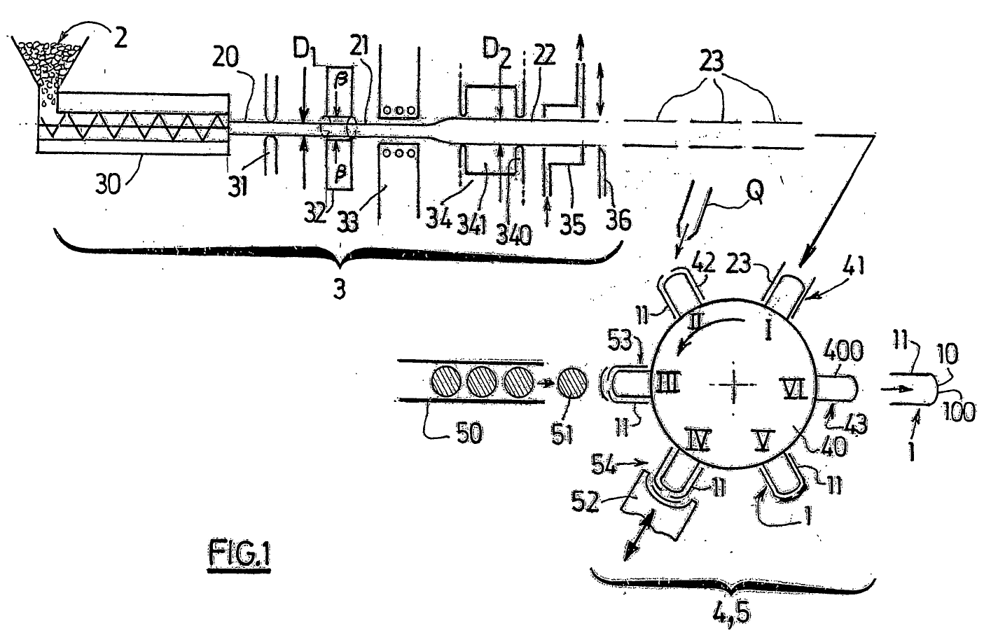

FIG. 1 illustrates a method of making portions of tube (23) according to the invention. The manufacturing line (3) for portions of tubes (23) shown in FIG. 1 shows one embodiment of the invention.

Usually, after step d) in which the said expanded tube (22) is cut into portions of tube (23), the said typically cylindrical portion of tube (23) obtained at the end of step d) can be transformed into a tapered portion of tube so as to form a truncated cone and to obtain a stackable cap, typically by placing the said portion of tube on a truncated mandrel and by heating said portion.

It is advantageous if the said portion of tube is placed on the said mandrel so as to curve the smallest diameter end of the truncated cone inwards, typically over a height varying from 1 to 5 mm, thus forming the skirt (11) of the cap (1) and facilitating assembly of the said head (10).

Thus, the same truncated mandrel (400) may be used firstly to transform a portion of the cylindrical tube into a truncated portion forming the said skirt (11), and then assembling the said head (10).

As shown in FIG. 2, this head (10) may be an injected head (10, 101) formed by injection of a thermoplastic material (60), typically the same as that used to form the said tube, on one end of the said portion of tube (23) or on the small diameter end, possibly curved inwards, of the said truncated cone formed from the said tube portion (23).

The said head (10, 100) can also be formed by gluing or heat sealing of a disk (51), that is either plane or with a curved edge, on one end of the said portion of tube (23) or on the small diameter end, possibly curved inwards, of the said truncated cone formed from the said portion of tube (23).

This disk (51) may be obtained by cutting out a sheet or strip of material (50), possibly transparent, into a material chosen from among plastic and metallic (aluminium, tin) materials, or paper, or cardboard or multiple layer assemblies of these materials. This method is shown in FIG. 1.

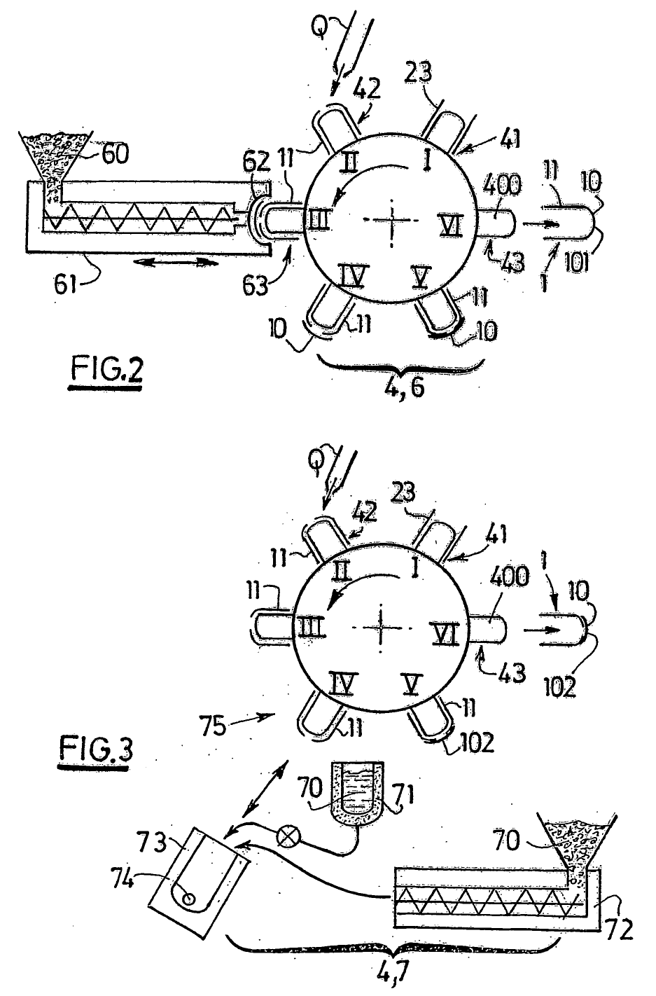

The said head (10, 102) can also be formed by moulding as shown in FIG. 3.

Regardless of the process used to form the said head (10, 100, 101, 102), the said head (10, 100, 101, 102, 103) is formed after forming the skirt (11) in the form of a truncated cone and possibly having its small diameter end curved inwards, by using the mandrel (400) that was used to form the said truncated skirt (11) as the inside support for the said truncated cone.

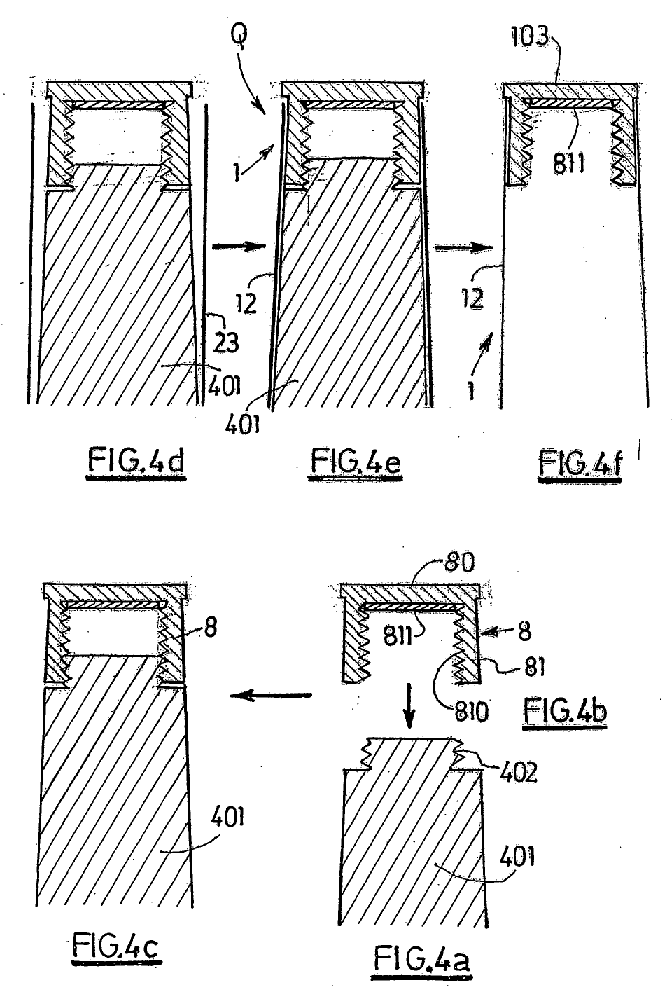

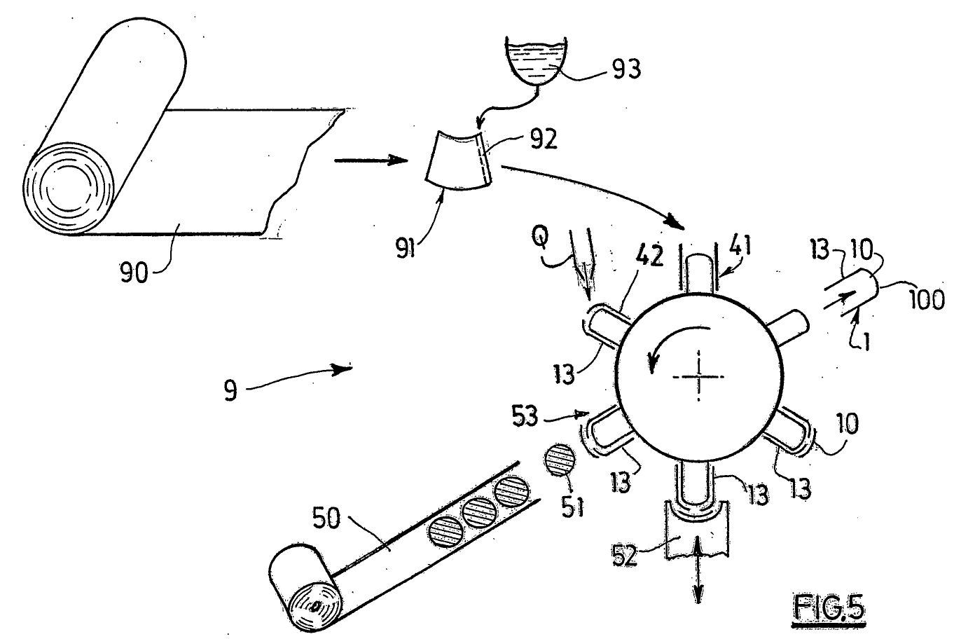

According to another variant of the invention, and as shown in FIGS. 4a to 4f, an insert (8) forming a head (80) and possibly comprising a skirt (81) may be placed at the small diameter end of the truncated mandrel (401) comprising the attachment means (402) of the insert (8) so as to assemble the said insert (8) to the said portion of tube (23), possibly using an adhesive or heat sealing layer or by direct welding, the said insert and the said skirt comprising a single thermoplastic material.

This insert may include threading (810), sealing means (811), typically a seal, so as to form a closing cap.

The said portion of tube (23) or the said skirt (11), possibly curved, may be printed either before assembling the said head, or possibly after the said head has been assembled and the said cap (1) has been formed.

This may be done using inks that can be cross linked under radiation, typically UV inks, so as to print on the said portion of tube or the said truncated cone with a possibly curved end, at a temperature less than the temperature at which the cap is heat shrunk.

With the process according to the invention, after step d) it is also possible to form two weakening lines on the said portion of tube (23) or on the said skirt (11, 12) that delimit a first opening strip, one end of which forms a manual gripping tab.

Another purpose of the invention is to make the different caps (1) that can be obtained with the process according to the invention:

firstly, overcaps with a height of between 20 and 60 mm with a skirt thickness of between 0.05 mm and 0.5 mm,

secondly, closing caps provided with an insert, with a height of between 20 and 60 mm, and with a skirt thickness of between 0.05 mm and 0.5 mm for the lower part of the skirt not assembled to the said insert,

finally, caps for sparkling wines or pressurized fizzy drinks with a height of between 60 and 200 mm, and with a skirt thickness between 0.1 mm and 1.0 mm.

These caps or overcaps are usually tapered, and are typically printed on their outside surface, and are therefore packaged in the form of sticks composed of stacks of caps of overcaps.

Example Embodiments

The processes described in FIGS. 1 to 3, and 4a to 4f, are example embodiments according to the invention.

In all cases, a PE tube is extruded to form the skirt of the cap or the overcap using the process and device shown in FIG. 1.

This device comprises an extruder (30), followed in sequence by a calibration ring (31), an annular β irradiation device (32), a heating device (33), an expansion device (34), a cooling system based on air circulation or water (35), and a cutting device (36).

All this equipment is standard equipment, except for the annular irradiation device (32) that was made for implementation of the invention and for carrying out tests.

An extruded tube (20) with a 20 mm diameter D₁ was formed in order to make 50 mm high or long tapered overcaps with a diameter equal to 29.5 mm for the head and 30.5 mm for the opening at the opposite end, at a rate of 30 m/minute.

The next step was to cross link this tube under β radiation with an installed power of 150 keV.

The cross-linked tube (21) was then expanded to a diameter D₂ of 30 mm using the expansion device (33) comprising calibration rings (340) that delimit an inside cavity under a relative vacuum (341) in order to obtain an expanded tube (22) that was then cut into 53 mm long tube portions (23).

Concerning the head (10) of the cap (1), the invention was then used according to the four modes described in FIGS. 1 to 4f.

All these modes were implemented using a carousel (40) typically with six stations, and provided with truncated supports or mandrels (400).

The tube portion (23) was placed on a mandrel (400) at station I.

The tube portion was heat shrunk at station II to make it tapered, to curve the outside end and thus form the skirt (11) by applying heat Q, typically by transferring hot air to the portion of tube (23).

The head is assembled or formed on the skirt on at least one of the following stations, depending on the variants described below.

The cap (1) formed according to the invention is ejected at station VI.

First variant: as shown in FIG. 1, an aluminium strip (50) coated with a thermoadhesive layer from which disks (51) were cut to be assembled to the skirt (11) in a manner known according to the state of the art, in order to form the head (100).

Tests were also carried out with a strip of transparent PE.

Second variant: as shown in FIG. 2, the head (101) on the skirt (11) carried by the mandrel (400) was injected using an extruder (61) supplied with PE (60).

Third variant: as shown in FIG. 3, the head (102) was moulded using a mould (73) in which a quantity of the PE material (70) was injected, possibly in the molten state, necessary to form the head, by closing the mould (73) on the skirt (11) carried by the mandrel (400). Depending on the material from which the head is made, the mould (73) may be supplied from an extruder (72) from a reservoir (71) containing materials (70) in the molten state, or from a hopper containing pellets. Depending on the case, the mould may be heated so as to melt the material (70) from which the head (102) is formed.

Fourth variant: as shown in FIGS. 4a to 4f, the carrousel mandrels (40) were adapted to obtain mandrels (401) with a threaded head (402) that can be used to fix the inserts (8) with threads (810) as shown in FIGS. 4a to 4c. After placing the tube portion (23) (see FIG. 4d), heating is applied by addition of heat Q so that the portion of tube (23) is heat shrunk, and in particular is assembled to the insert (8).

An expandable mandrel is also used to facilitate expulsion of the cap once it has been formed.

Caps for Champagne wines were also made using the same processes. The height of these caps was 120 mm and their diameters were 33 mm for the head and 50 mm for the opening at the opposite end.

### ADVANTAGES OF THE INVENTION

The invention has many advantages to the extent that it can be used to obtain caps or overcaps that are very aesthetic in themselves, but particularly after being heat shrunk onto bottlenecks.

The process according to the invention may also be used to obtain composite caps or overcaps made from various materials to the extent that different materials can be chosen for the head and the skirt of the cap, which can be commercially very attractive, and very many possibilities for differentiation can be introduced.

Finally, the process according to the invention is particularly economical, because it can use the cheapest materials that exist, in particular PE, because it enables high speeds and also because most equipment necessary for use of the process is standard and inexpensive.

List of marks

| | |
|---|---|
| Cap or overcap | 1 |
| Head | 10 |
| Assembled head | 100 |
| Injected head | 101 |
| Moulded head | 102 |
| Head formed from an insert | 103 |
| Skirt | 11 |
| Skirt assembled to an insert | 12 |
| Rolled skirt according to | 13 |
| the state of the art | |
| Skirt plastic material | 2 |
| Extruded tube | 20 |
| Cross-linked tube | 21 |
| Expanded tube | 22 |
| Portions of tube | 23 |
| Manufacturing line for portions | 3 |
| of tubes 23 | |
| Extruder | 30 |
| Calibration | 31 |
| Annular β irradiation device | 32 |
| Heating device | 33 |
| Expansion device | 34 |
| Calibration rings | 340 |
| Internal cavity under | 341 |
| relative vacuum | |
| Cooling device | 35 |
| Cutting device | 36 |
| Cap formation line | 4 |
| Carousel | 40 |
| Mandrels - supports | 400 |
| Mandrel for insert | 401 |
| Head | 402 |
| Loading station I | 41 |
| End tapering and curvature station II | 42 |
| Cap 1 ejection stations VI | 43 |
| Formation line for the | 5 |
| first head type | |
| Material strip for the head | 50 |
| Cut-out disk in strip 50 | 51 |
| Heat sealing matrix | 52 |
| Head disk formation station III | 53 |
| Head disk heat-sealing station IV | 54 |
| Formation line for the | 6 |
| second head type | |
| Head plastic material | 60 |
| Head material extruder | 61 |
| Head injection matrix | 62 |
| Head extrusion station III | 63 |
| Formation line for the | 7 |
| third head type | |
| Head plastic material | 70 |
| Molten material reservoir | 71 |
| Extruder | 72 |
| Mould | 73 |
| Head material “grain” | 74 |
| Head moulding station IV | 75 |
| Insert for the fourth head type | 8 |
| Insert head | 80 |
| Insert skirt | 81 |
| Skirt inside thread | 810 |
| Seal | 811 |
| Line according to the state | 9 |
| of the art | |
| Skirt material strip | 90 |
| Blank or cut out portion of strip | 91 |
| Lateral adhesive strip | 92 |
| Adhesive | 93 |

1. Process for manufacturing caps or overcaps with heat shrinking skirts (1) in which:
a) an extruded tube (20) is formed by extrusion of a thermoplastic material, typically chosen from among polyolefins, with a diameter D₁, at the exit from the extruder,
b) the said extruded tube with diameter D1 is then subjected to an irradiation treatment typically applied to the said extruded tube using an annular irradiation device (32) surrounding the said extruded tube (20), so as to cross link the said polyolefin and form a cross-linked tube (21),
c) the said cross-linked tube (21) is warmed up to a temperature equal to at least approximately the melting temperature of its crystalline phase, and is then subjected to a monoaxial radial expansion, while moving, to form an expanded tube (22) with diameter D2, and is then cooled to the temperature at which it can be cut into portions, typically ambient temperature,
d) the said expanded tube (22) is then cut into tube portions (23) with a length approximately equal to the height of the said caps (1), and
e) a head (10, 100, 101, 102, 103) is then assembled or formed on the said portion of tube (23),
so as to obtain an economical cap or overcap (1) with a heat shrinking skirt (11, 12) that has a homogenous skirt with no axial connection line.

2. Process according to claim 1 in which the said tube (20) may be cooled and calibrated at the exit from the extruder and before the said irradiation processing, so as to impose predetermined geometric characteristics on the said tube.

3. Process according to any one of claims 1 to 2, in which in step c) in the process, the said monoaxial expansion takes place completely or partly during the phase in which the tube is cooled.

4. Process according to any one of claims 1 to 3 in which the said plastic material (2) comprises a polyolefin chosen from among PE, PP and PB, ethylene and propylene copolymers, or an elastomer, or a mix of these different polymers in the form of a single layer material or a multiple layer material.

5. Process according to claim 4, in which the said plastic material is composed of a single layer material made of a polyolefin chosen from among PE or PP.

6. Process according to any one of claims 1 to 5, in which the said plastic material (2) contains a micronized charge typically chosen from among talc, calcium carbonate, barium sulphate, titanium oxide, organic or mineral pigments.

7. Process according to any one of claims 1 to 6 in which the said irradiation treatment is an ionising radiation chosen from among β and γ radiation.

8. Process according to claim 7, in which the said irradiation treatment is preferably an electronic bombardment or β radiation.

9. Process according to any one of claims 1 to 8, in which D₁ is between 10 mm and 30 mm, the ratio D₂/D₁ is between 1.5 and 4.

10. Process according to any one of claims 1 to 9, in which the said radial monoaxial expansion is obtained either by keeping the inside of the said cross-linked tube (21) under pressure, or by keeping the outside of the said cross-linked tube (21) under a vacuum.

11. Process according to claim 10, in which the said radial monoaxial expansion is obtained by keeping the outside of the said cross-linked tube (21) under a vacuum.
